(19) United States
(12) Patent Application Publication
(10) Pub. No.: US 2026/0107835 A1
(43) Pub. Date: Apr. 16, 2026

(54) SEMICONDUCTOR PACKAGE

(71) Applicant: Samsung Electronics Co., Ltd., Suwon-si (KR)

(72) Inventors: Junbae KIM, Suwon-si (KR); Geunwoo KIM, Suwon-si (KR); Byoung-Gug MIN, Suwon-si (KR)

(73) Assignee: Samsung Electronics Co., Ltd., Suwon-si (KR)

(21) Appl. No.: 19/188,488

(22) Filed: Apr. 24, 2025

(30) Foreign Application Priority Data
Oct. 11, 2024 (KR) 10-2024-0138509

(51) Int. Cl. H01L 25/16; H01L 23/00; H01L 23/31; H01L 23/498; H01L 23/538; H01L 23/64; H10B 80/00; H10D 80/20; H10D 80/30

(52) U.S. Cl. CPC H10W 90/00; H10D 80/215; H10W 44/601; H10W 70/611; H10W 70/65; H10W 74/117; H10W 90/401; H10B 80/00; H10D 80/30; H10W 72/0198; H10W 72/877; H10W 74/15; H10W 90/724; H10W 90/734; H10W 90/754

(57) ABSTRACT

A semiconductor package may include a package substrate including a plurality of upper pads, a semiconductor chip on the package substrate and electrically connected to at least one of the plurality of upper pads, a sealing layer covering at least a portion of the semiconductor chip and the package substrate, and a capacitor structure including a first conductive layer covering one side surface of the package substrate and a portion of the sealing layer, a second conductive layer covering another side surface of the package substrate and another portion of the sealing layer, and a dielectric layer being between the first conductive layer and the second conductive layer.

### CROSS-REFERENCE TO RELATED APPLICATION

This application claims priority to and the benefit of Korean Patent Application No. 10-2024-0138509 filed in the Korean Intellectual Property Office on Oct. 11, 2024, the entire contents of which are incorporated herein by reference.

### BACKGROUND

### (a) Field

The present disclosure relates to semiconductor packages.

### (b) Description of the Related Art

With the weight reduction and/or performance improvement of electronic devices, it is being desired to develop packages capable of protecting semiconductor chips from electromagnetic interference (EMI). Research and development of semiconductor packages with EMI shielding structures on the outside of the semiconductor packages is ongoing.

### SUMMARY

Some example embodiments of the present disclosure provide semiconductor packages with improved electricity storage capacity.

Some example embodiments of the present disclosure provide semiconductor packages with an improved shielding characteristic.

According to an example embodiment, a semiconductor package may include a package substrate that includes a plurality of upper pads, a semiconductor chip on the package substrate and is electrically connected to at least one of the plurality of upper pads, a sealing layer that covers at least a portion of the semiconductor chip and the package substrate, and a capacitor structure that includes a first conductive layer which covers one side surface of the package substrate and a portion of the sealing layer, a second conductive layer which covers another side surface of the package substrate and another portion of the sealing layer, and a dielectric layer being between the first conductive layer and the second conductive layer.

According to an example embodiment, a semiconductor package may include a package substrate including a plurality of upper pads, a semiconductor chip on the package substrate and electrically connected to at least one of the plurality of upper pads, a sealing layer configured to cover at least a portion of the semiconductor chip and the package substrate, the sealing layer including a connection structure electrically connected to a second conductive layer, and a capacitor structure including a first conductive layer which covers one side surface of the package substrate and a portion of the sealing layer, the second conductive layer which covers another side surface of the package substrate and another portion of the sealing layer, and a dielectric layer being between the first conductive layer and the second conductive layer.

According to an example embodiment, a semiconductor package may include a package body including a package substrate including a first wiring layer and a second wiring layer, a semiconductor chip on the package substrate and electrically connected to the first wiring layer, and a sealing layer configured to cover at least a portion of the semiconductor chip and the package substrate, a capacitor structure including a first conductive layer in contact with one side surface of the package body, a second conductive layer in contact with another side surface and the upper surface of the package body, and a dielectric layer being between the first conductive layer and the second conductive layer, a conductive structure in contact with the second conductive layer of the capacitor structure, a base substrate including a first connection wiring line below the package body and the conductive structure and electrically connected to the first wiring layer, a second connection wiring line electrically connected to the second wiring layer, and a third connection wiring line electrically connected to the conductive structure, and a first connection bump, a second connection bump, and a third connection bump being below the base substrate and electrically connected to the first connection wiring line, the second connection wiring line, and the third connection wiring line, respectively.

According to an example embodiment, a method of manufacturing a semiconductor package may include providing a first package assembly by attaching a plurality of semiconductor chips attached to one surface of the package substrate and surrounding and sealing the plurality of semiconductor chips on the one surface of the package substrate using a sealing layer, cutting the first package assembly in a direction perpendicular to the package substrate to provide a plurality of package bodies, placing one package body of a plurality of package bodies on a support substrate, forming a first conductive layer including a first portion covering a first side surface of the one package body and one or more second portions extending from the first portion in a horizontal direction and being above an upper surface of the one package body, forming a second conductive layer including a third portion covering another side surface of the one package body, a fourth portion extending from the third portion in the horizontal direction and being in contact with an upper surface of the one package body, and a fifth portion extending from the third portion in the horizontal direction and being above the fourth portion, the one or more second portions of the first conductive layer being between the fourth portion and the fifth portion of the second conductive layer, and forming a dielectric layer between the first conductive layer and the second conductive layer.

The providing the first package assembly may further include providing a connection structure on the one surface of the package substrate and to be connected to a corresponding one of a plurality of upper pads exposed from the one surface of the package substrate, the plurality of upper pads being connected to a plurality of connection bumps on the another surface of the package substrate via connection wiring lines in the package substrate.

### BRIEF DESCRIPTION OF THE DRAWINGS

FIG. 1 is a cross-sectional view illustrating a semiconductor package according to an example embodiment of the present disclosure.

FIG. 2 is a top view of the semiconductor package of FIG. 1 as seen from above.

FIG. 3 is a cross-sectional view illustrating a semiconductor package according to an example embodiment.

FIG. 4 is a cross-sectional view illustrating a semiconductor package according to an example embodiment.

FIG. 5 is a cross-sectional view illustrating a semiconductor package according to an example embodiment of the present disclosure.

FIGS. 6 to 8 are cross-sectional views schematically illustrating a process of manufacturing a semiconductor package according to an example embodiment of the present disclosure.

FIG. 9 is a cross-sectional view illustrating a semiconductor package according to an example embodiment of the present disclosure.

FIG. 10 is a top view of the semiconductor package of FIG. 9 as seen from above.

FIG. 11 is a cross-sectional view illustrating a semiconductor package according to an example embodiment of the present disclosure.

FIG. 12 is a top view of the semiconductor package of FIG. 11 as seen from above.

FIGS. 13 to 15 are cross-sectional views schematically illustrating a process of manufacturing the semiconductor package of FIG. 11 of the present disclosure.

FIG. 16 is a cross-sectional view illustrating a semiconductor package according to an example embodiment of the present disclosure.

FIG. 17 is a top view of the semiconductor package of FIG. 16 as seen from above.

### DETAILED DESCRIPTION

In the following detailed description, only certain example embodiments of the present inventive concepts have been shown and described, simply by way of illustration. As those skilled in the art would realize, the described embodiments may be modified in various different ways, all without departing from the spirit or scope of the present inventive concepts.

Accordingly, the drawings and description are to be regarded as illustrative in nature and not restrictive. Like reference numerals designate like elements throughout the specification. In the flow charts described with reference to the drawings, the order of operations may be changed, and several operations may be combined, and an operation may be divided, and some operations may not be performed.

Further, the singular forms “a,” “an” and “the” are intended to include the plural forms as well, unless the context clearly indicates otherwise (e.g., unless a clear expression such as “single” is used). Terms including an ordinal number, such as first and second, are used for describing various constituent elements, but the constituent elements are not limited by the terms. The terms are used only to discriminate one constituent element from other constituent elements.

Further, the size and thickness of each component shown in the drawings are an example for explaining an example embodiment, and the present inventive concepts is not necessarily limited thereto. In the drawings, various layers and regions are shown with arbitrary thicknesses for explaining the corresponding layers and regions. Further, in the drawings, for ease of explanation, the thicknesses of some layers and regions may be exaggerated.

Further, it will be understood that when an element such as a layer, film, region, or substrate is referred to as being “on” another element, it can be directly on the other element or intervening elements may also be present. In contrast, when an element is referred to as being “directly on” another element, there are no intervening elements present. Further, when an element is “on” a reference portion, the element is located above or below the reference portion, and it does not necessarily mean that the element is located “above” or “on” in a direction opposite to gravity.

As used herein, expressions such as “one of,” “one or more of,” “any one of,” and “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

Further, in the entire specification, when it is referred to as “on a plane”, it means when a target part is viewed from above, and when it is referred to as “on a cross-section”, it means when the cross-section obtained by cutting a target part vertically is viewed from the side.

Hereinafter, the present disclosure will be described in more detail through examples. These examples are just for illustrating the present disclosure, and the right protection scope of the present disclosure is not limited by the examples.

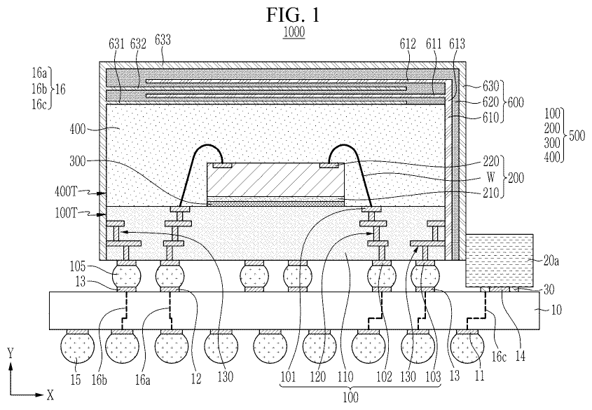

FIG. 1 is a cross-sectional view illustrating a semiconductor package according to an example embodiment of the present disclosure.

Referring to FIG. 1, a semiconductor package 1000 according to an example embodiment may include a base substrate 10, a conductive structure 20a, an adhesive layer 30, a package body 500, and a capacitor structure 600. The package body 500 may include a package substrate 100, a semiconductor chip 200, an adhesive film 300, and a sealing layer 400.

The semiconductor chip 200 may include memory chips or memory devices which store or output data on the basis of an address, a command, and data received from the package substrate 100. For example, the semiconductor chip 200 may include a logic chip (or ‘logic circuit’) such as a central processing unit (CPU), a graphic processing unit (GPU), a field-programmable gate array (FPGA), an application processor (AP), a digital signal processor (DSP), a cryptographic processor, a microprocessor, a micro controller, an analog-to-digital converter, or an application-specific IC (ASIC), or a memory chip (or ‘memory circuit’) including a volatile memory such as a dynamic RAM (DRAM) or a static RAM (SRAM) or a non-volatile memory such as a phase change RAM (PRAM), a magnetic RAM (MRAM), a resistive RAM (RRAM), or a flash memory, and so on.

The semiconductor chip 200 may be attached to the package substrate 100 via the adhesive film 300. The adhesive film 300 may be disposed between the semiconductor chip 200 and the package substrate 100. The adhesive film 300 may physically couple the semiconductor chip 200 and the package substrate 100. The adhesive film 300 may electrically connect the semiconductor chip 200 and the package substrate 100. The adhesive film 300 may include a silicon-based adhesive or an acryl adhesive.

The semiconductor chip 200 may include an adhesive film 210. The semiconductor chip 200 may be attached to the upper surface of the package substrate 100, using the adhesive film 210. The adhesive film 210 of the semiconductor chip may be bonded to the adhesive film 300. The adhesive film 210 may include a silicon-based adhesive or an acryl adhesive.

The semiconductor chip 200 may include a conductive pad 220. The semiconductor chip 200 may be electrically connected to the package substrate 100 through conductive wire W connected to the conductive pad 220 and an upper pad 101 of the package substrate 100.

The package substrate 100 may include an insulating layer 110, the upper pad 101, lower pads 102 and 103, and a plurality of wiring layers 120 and 130. The package substrate 100 may transmit a data signal, received from the semiconductor chip 200 disposed thereon, to the outside. The package substrate 100 may transmit a data signal and a power signal, received from the outside, to the semiconductor chip 200.

The insulating layer 110 may contain an insulating resin. The insulating resin may include a thermosetting resin and a thermoplastic resin. The thermosetting resin may include an epoxy resin. The thermoplastic resin may include polyimide. The insulating resin may include an insulating resin or a thermoplastic resin including an inorganic filler immersed in the resin. For example, the insulating resin may include prepreg, Ajinomoto build-up film (ABF), FR-4, and bismaleimide-triazine (BT). The insulating layer 110 may contain a photosensitivity resin. The photosensitivity resin may include a photo-imageable dielectric (PID) material. The insulating layer 110 may include a plurality of insulating layers (not shown in the drawings) stacked in the vertical direction.

The upper pad 101 may be disposed in the upper portion of the package substrate 100. The upper surface of the upper pad 101 may be exposed from the upper surface of the package substrate 100. The upper pad 101 may contain at least one of aluminum (Al), copper (Cu), nickel (Ni), tungsten (W), platinum (Pt), or gold (Au). The lower pads 102 and 103 may be disposed on the lower portion of the package substrate 100. The lower pads 102 and 103 may contain at least one of aluminum (Al), copper (Cu), nickel (Ni), tungsten (W), platinum (Pt), or gold (Au). The materials of the upper pad 101 and the lower pads 102 and 103 are not limited to the above-mentioned materials.

The plurality of wiring layers 120 and 130 may be connected to the lower pads 102 and 103 at the lower end of the package substrate 100. The plurality of wiring layers 120 and 130 may include a first wiring layer 120 that is electrically connected to the semiconductor chip 200, and a second wiring layer 130 that is electrically connected to the capacitor structure 600.

The first wiring layer 120 may be connected to the upper pad 101 exposed from the upper end of the package substrate 100. The first wiring layer 120 may be electrically connected to the semiconductor chip 200 through the upper pad 101 of the package substrate 100. The second wiring layer 130 may be in contact with a first conductive layer 610 and a second conductive layer 630. The second wiring layer 130 may be in contact with two side surfaces of the package substrate 100 facing each other. The second wiring layer 130 may be electrically connected to the first conductive layer 610 and the second conductive layer 630. Each of the first wiring layer 120 and the second wiring layer 130 may be electrically insulated.

The plurality of wiring layers 120 and 130 may be formed in multi-layer structures including wiring patterns and vias including aluminum (Al), gold (Au), cobalt (Co), copper (Cu), nickel (Ni), lead (Pb), tantalum (Ta), tellurium (Te), titanium (Ti), tungsten (W), or a combination thereof.

The sealing layer 400 may cover at least some portions of the semiconductor chip 200 and the package substrate on the package substrate 100. The horizontal area of the sealing layer 400 may be equal to the horizontal area of the package substrate 100. For example, a side surface 400T of the sealing layer may be coplanar with a side surface 100T of the package substrate 100. The sealing layer 400 may be formed of or include an insulating material such as an epoxy mold compound (EMC). The insulating material forming the sealing layer 400 is not limited thereto.

The capacitor structure 600 may include the first conductive layer 610, a dielectric layer 620, and the second conductive layer 630 which are stacked on two side surfaces and the upper surface of the package body 500.

The second conductive layer 630 may be in contact with the package substrate 100 and one side surface of the sealing layer 400 and cover the package substrate 100 and the sealing material 400. The second conductive layer 630 may include a (2−1)-st branch region 631, a (2−2)-nd branch region 632, and a second cover region 633. The (2−1)-st branch region 631 and the (2−2)-nd branch region 632 may branch from the second cover region 633. The (2−1)-st branch region 631 and the (2−2)-nd branch region 632 may be disposed in a first axis (X) direction. The length of the (2−1)-st branch region 631 in the first axis (X) direction may be equal to the length of the (2−2)-nd branch region 632 in the first axis (X) direction. The area of the (2−1)-st branch region 631 may be equal to the area of the (2−2)-nd branch region 632. The (2−1)-st branch region 631 and the (2−2)-nd branch region 632 may be disposed so as to be spaced apart from each other.

The (2−1)-st branch region 631 may be disposed on the upper end of the sealing layer 400. The (2−1)-st branch region 631 may be in contact with the sealing layer 400. The (2−2)-nd branch region 632 may be disposed in a second axis (Y) direction from the (2−1)-st branch region 631.

The second cover region 633 may be in contact with one side surface of the package body 500. The second cover region 633 may include or define an upper end region of the capacitor structure 600. The upper end region may be disposed in the second axis (Y) direction from the (2−2)-nd branch region 632. The second cover region 633 may overlap the package body 500 with the dielectric layer 620 interposed between the second cover region and the other side surface and upper surface of the package body 500

The first conductive layer 610 may be in contact with the package substrate 100 and the other side surface of the sealing layer 400, and cover the package substrate 100 and the sealing layer 400. The first conductive layer 610 may include a (1−1)-st branch region 611, a (1−2)-nd branch region 612, and a first cover region 613. The (1−1)-st branch region 611 and the (1−2)-nd branch region 612 may branch from the first cover region 613. The (1−1)-st branch region 611 and the (1−2)-nd branch region 612 may be disposed in a first axis (X) direction. The length of the (1−1)-st branch region 611 in the first axis (X) direction may be equal to the length of the (1−2)-nd branch region 612 in the first axis (X) direction. The area of the (1−1)-st branch region 611 may be equal to the area of the (1−2)-nd branch region 612. The (1−1)-st branch region 611 and the (1−2)-nd branch region 612 may be disposed so as to be spaced apart from each other.

The (1−1)-st branch region 611 may be disposed between the (2−1)-st branch region 631 and the (2−2)-nd branch region 632. The (1−1)-st branch region 611 may be disposed so as to be spaced apart from the (2−1)-st branch region 631 and the (2−2)-nd branch region 632.

The (1−2)-nd branch region 612 may be disposed between the (2−2)-nd branch region 632 and the second cover region 633. The (1−2)-nd branch region 612 may be disposed so as to be spaced apart from the (2−2)-nd branch region 632 and the second cover region 633.

The first cover region 613 may be in contact with the other side surface of the package body 500. The first cover region 613 may be disposed so as to be spaced apart from the second cover region 633.

The dielectric layer 620 may be disposed on the other side surface and upper surface of the package body 500. The dielectric layer 620 may be disposed between the first conductive layer 610 and the second conductive layer 630 on the upper end of the package substrate 100 and the other side surface of the package substrate 100. On the other side surface of the package body 500, the dielectric layer 620 may be disposed between the second cover region 633 and the first cover region 613. On the upper surface of the package body 500, the dielectric layer 620 may be disposed in a first region which is positioned between the second cover region 633 and the (1−2)-nd branch region 612. The dielectric layer 620 may be disposed in a second region which is positioned between the (1−2)-nd branch region 612 and the (2−2)-nd branch region 632. The dielectric layer 620 may be disposed in a third region which is positioned between the (2−2)-nd branch region 632 and the (1−1)-st branch region 611. The dielectric layer 620 may be disposed in a fourth region which is positioned between the (1−1)-st branch region 611 and the (2−1)-st branch region 631.

The first conductive layer 610 and the second conductive layer 630 may include a metal material including tin (Sn), iron (Fe), nickel (Ni), or an alloy thereof. The dielectric layer 620 may include a dielectric material such as zirconium oxide (ZrO₂) and hafnium oxide (HfO₂). The dielectric layer 620 may contain a dielectric material having a dielectric constant equal to or larger than about 20, for example, about 20 to about 30, or about 20 to about 25. The electrical conductivity of the first conductive layer 610 may be equal to the electrical conductivity of the second conductive layer 630. The electrical conductivity of the first conductive layer 610 and the second conductive layer 630 may be higher than the electrical conductivity of the dielectric layer 620.

Each of the first conductive layer 610, the dielectric layer 620, and the second conductive layer 630 may have a constant thickness. The thickness of the plurality of layers 610, 620, and 630 stacked on the upper surface of the package body 500 may be larger than the thickness of the plurality of layers 610, 620, and 630 stacked on the other side surface of the package body 500.

The dielectric layer 620 disposed on the upper surface of the package body 500 may have a larger thickness than at least one layer of the first and second conductive layers 610 and 630 disposed on the upper surface of the package body 500. For example, the dielectric layer 620 may have a thickness of about 5 μm or less, about 10 nm to about 5 μm, about 50 nm to about 2 μm, or about 100 nm to about 1 μm. The first and second conductive layers 610 and 630 may have a thickness of about 1 μm or less, about 100 nm to about 1 μm, or about 200 nm to about 0.5 μm.

The first conductive layer 610 may be in contact with the second wiring layer 130 of the package substrate 100 on the other side surface of the package substrate 100. The second wiring layer 130 may provide an electrical connection path to the first conductive layer 610. The first conductive layer 610 may receive a first voltage V1 through the second wiring layer 130.

The second conductive layer 630 may be in contact with the second wiring layer 130 of the package substrate 100 on one side surface of the package substrate 100. The second wiring layer 130 may provide an electrical connection path to the second conductive layer 630. The second conductive layer 630 may receive the first voltage V1 through the second wiring layer 130.

The conductive structure 20a may provide an electrical connection path to the second conductive layer 630. The second conductive layer 630 may receive a second voltage V2 through the conductive structure 20a. The first voltage V1 which is applied to the first conductive layer 610 may be larger than the second voltage V2 which is applied to the second conductive layer 630. The first voltage V1 may be Vdd (e.g., a supply voltage), and the second voltage V2 may be Vss (e.g., a ground voltage).

The capacitor structure 600 may be a multi-layer capacitor structure in which a plurality of capacitors is connected in parallel. The (2−1)-st branch region 631 to which the second voltage is applied, the (1−1)-st branch region 611 to which the first voltage is applied, and the dielectric layer 620 which is disposed between the (2−1)-st branch region 631 and the (1−1)-st branch region 611 may constitute a first capacitor. The (1−1)-st branch region 611 to which the first voltage is applied, the (2−2)-nd branch region 632 to which the second voltage is applied, and the dielectric layer 620 which is disposed between the (1−1)-st branch region 611 and the (2−2)-nd branch region 632 may constitute a second capacitor. The (2−2)-nd branch region 632 to which the second voltage is applied, the (1−2)-nd branch region 612 to which the first voltage is applied, and the dielectric layer 620 which is disposed between the (2−2)-nd branch region 632 and the (1−2)-nd branch region 612 may constitute a third capacitor. The (1−2)-nd branch region 612 to which the first voltage is applied, the second cover region 633 to which the second voltage is applied, and the dielectric layer 620 which is disposed between the (1−2)-nd branch region 612 and the second cover region 633 may constitute a fourth capacitor. The capacitor structure 600 may be a multi-layer capacitor structure in which the first capacitor to the fourth capacitor are connected in parallel.

The multi-layer capacitor structure may store more charge than a single-layer capacitor structure. The capacitance of the multi-layer capacitor structure may be calculated by summing the capacitance of each of the capacitors connected in parallel. As the number of capacitors connected in parallel increases, the capacitance of the multi-layer capacitor structure may increase. Because the multi-layer capacitor structure stores more charge than a single-layer capacitor structure, the electricity storage capacity may increase.

The multi-layer capacitor structure may improve a shielding effect of protecting internal circuits from external electromagnetic interference (EMI). The multi-layer capacitor structure may block high-frequency noise generated outside. The structure in which the plurality of conductive layers 610 and 630 and the dielectric layer 620 are connected in parallel may distribute the electrical path. In the structure in which the plurality of conductive layers 610 and 630 and the dielectric layer 620 are connected in parallel, the dielectric layer 620 may serve as a filter to suppress noise.

On the lower surface of the package body 500, the base substrate 10 may be disposed. The base substrate 10 may include a back surface pad 11, front surface pads 12, 13, and 14, and connection wiring lines 16a, 16b, and 16c.

The base substrate 10 may be a substrate which includes an electric circuit configured by fixing electronic components such as resistors, capacitors, and/or integrated circuits to the surface and connecting the components by wiring lines, but the present inventive concepts are not limited thereto.

The back surface pad 11 may be disposed on the lower surface of the base substrate 10. The back surface pad 11 may include at least one material of aluminum (Al), copper (Cu), nickel (Ni), tungsten (W), platinum (Pt), and gold (Au).

The front surface pads 12, 13, and 14 may be disposed on the front surface of the base substrate 10. The front surface pads 12, 13, and 14 may include at least one material of aluminum (Al), copper (Cu), nickel (Ni), tungsten (W), platinum (Pt), and gold (Au). The materials constituting the back surface pad 11 and the front surface pads 12, 13, and 14 are not limited thereto.

At least some of the front surface pads 12, 13, and 14 may be disposed with at least some of the lower pads 102 and 103 of the package substrate 100 on the same line. At least some of the front surface pads (e.g., the front surface pad 14) may be a connection pad which is disposed below the conductive structure 20a and provides an electrical connection path therethrough.

The base substrate 10 may include the plurality of connection wiring lines 16a, 16b, and 16c which electrically connects each of the lower pads 102 and 103 of the package substrate 100 and the conductive structure 20a to the back surface pad 11. The plurality of connection wiring lines 16a, 16b, and 16c may include the first connection wiring line 16a which connects the first lower pad 102 that is in contact with the first wiring layer 120 and the back surface pad 11. The plurality of connection wiring lines 16a, 16b, and 16c may include the second connection wiring line 16b which connects the second lower pad 103 that is in contact with the second wiring layer 130 and the back surface pad 11. The plurality of connection wiring lines 16a, 16b, and 16c may include the third connection wiring line 16c which connects the conductive structure 20a and the back surface pad 11.

The semiconductor chip 200 may be electrically connected to the base substrate 10 through the first connection wiring line 16a and the first wiring layer 120. The first conductive layer 610 may be electrically connected to the base substrate 10 through the second connection wiring line 16b and the second wiring layer 130. The second conductive layer 630 may be electrically connected to the base substrate 10 through the third connection wiring line 16c and the conductive structure 20a.

The plurality of connection wiring lines 16a, 16b, and 16c may be formed in multi-layer structures including wiring patterns and vias including aluminum (Al), gold (Au), cobalt (Co), copper (Cu), nickel (Ni), lead (Pb), tantalum (Ta), tellurium (Te), titanium (Ti), tungsten (W), or a combination thereof.

Between the package body 500 and the base substrate 10, a plurality of bump structures 105 may be disposed. The plurality of bump structures 105 may electrically connect at least some of the lower pads 102 and 103 of the package substrate 100 and corresponding ones of the front surface pads 12, 13, and 14 of the base substrate 10, respectively. The plurality of bump structures 105 may include tin (Sn), indium (In), bismuth (Bi), antimony (Sb), copper (Cu), silver (Ag), zinc (Zn), lead (Pb), and/or an alloy thereof. The alloy may include Sn—Pb, Sn—Ag, Sn—Au, Sn—Cu, Sn—Bi, Sn—Zn, Sn—Ag—Cu, Sn—Ag—Bi, Sn—Ag—Zn, Sn—Cu—Bi, Sn—Cu—Zn, and Sn—Bi—Zn. The material constituting the plurality of bump structures 105 is not limited thereto.

On the lower surface of the base substrate 10, a plurality of connection bumps 15 including a first connection bump, a second connection bump, and a third connection bump may be additionally disposed. The plurality of connection bumps 15 may be disposed so as to be in contact with the back surface pads 11 disposed on the lower surface of the base substrate 10, respectively. The plurality of connection bumps 15 may include tin (Sn), indium (In), bismuth (Bi), antimony (Sb), copper (Cu), silver (Ag), zinc (Zn), lead (Pb), and/or an alloy thereof. The alloy may include Sn—Pb, Sn—Ag, Sn—Au, Sn—Cu, Sn—Bi, Sn—Zn, Sn—Ag—Cu, Sn—Ag—Bi, Sn—Ag—Zn, Sn—Cu—Bi, Sn—Cu—Zn, and Sn—Bi—Zn. The material which constituting the plurality of connection bumps 15 is not limited thereto.

On the base substrate 10, the conductive structure 20a may be disposed. The conductive structure 20a may be in contact with the outer surface of the second conductive layer 630. The second conductive layer 630 may be in contact with the conductive structure 20a so as to provide an electrical connection path. The conductive structure 20a may include a conductive material such as iron (Fe), nickel (Ni), tin (Sn), or molybdenum (Mo).

Between the conductive structure 20a and the base substrate 10, the adhesive layer 30 may be disposed. The adhesive layer 30 may include an adhesive polymeric material such as a polymeric binder resin, an epoxy-based resin, a phenolic epoxy curing agent, a curing catalyst, or a silane coupling agent. The adhesive layer 30 may be in the form of paste or film.

The adhesive layer 30 may be disposed to surround the front surface pad 14 (e.g., connection pad), which is disposed between the conductive structure 20a and the base substrate 10. The thicknesses of the front surface pad 14 (e.g., connection pad) and the adhesive layer 30 may be equal.

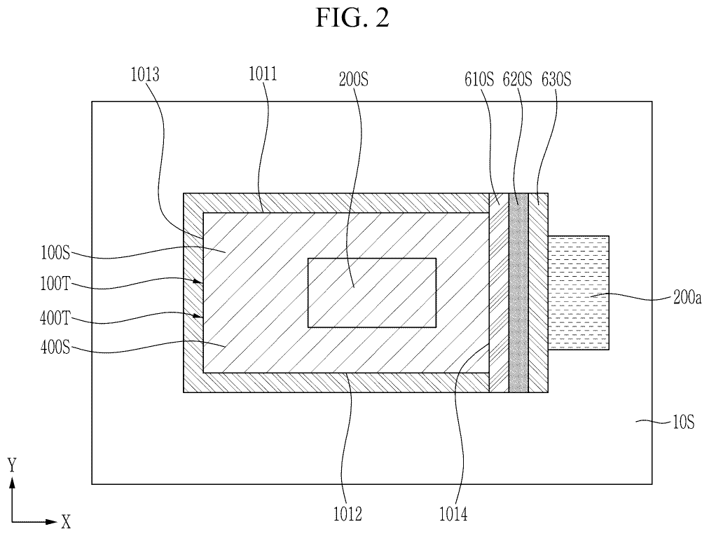

FIG. 2 is a top view of the semiconductor package of FIG. 1 as seen from above.

Referring to FIG. 2. the horizontal area 100S of the package substrate (reference symbol “100” in FIG. 1) in the first axis (X) direction and the second axis (Y) direction may be equal to the horizontal area 400S of the sealing layer (reference symbol “400” in FIG. 1) in the first axis (X) direction and the second axis (Y) direction. The side surface 100T of the package substrate 100 may be coplanar with the side surface 400T of the sealing layer 400 in the second axis (Y) direction.

The horizontal area 100S of the package substrate 100 may be included in the horizontal area 10S of the substrate (reference symbol “10” in FIG. 1). The horizontal area 100S of the package substrate 100 may be surrounded by the horizontal area 610S of the first conductive layer and the horizontal area 630S of the second conductive layer. A first edge 1011 and a second edge 1012 in the horizontal area 100S of the package substrate 100 may be surrounded by the horizontal area 630S of the second conductive layer arranged in the second axis (Y) direction and extending in the first axis (X) direction. A third edge 1013 in the horizontal area 100S may be surrounded by the horizontal area 630S of the second conductive layer arranged in the first axis (X) direction and extending in the second axis (second) direction. A fourth edge 1014 in the horizontal area 100S may be surrounded by the horizontal area 610S of the first conductive layer arranged in the first axis (X) direction and extending in the second axis (second) direction.

The horizontal area 610S of the first conductive layer may be disposed between the horizontal area 620S of the dielectric layer and the horizontal area 100S of the package substrate 100. The horizontal area 620S of the dielectric layer may be positioned in the first axis (X) direction from the horizontal area 610S of the first conductive layer.

The horizontal area 620S of the dielectric layer may be disposed between the horizontal area 630S of the second conductive layer and the horizontal area 610S of the first conductive layer. The horizontal area 630S of the second conductive layer may be positioned in the first axis (X) direction from the horizontal area 620S of the dielectric layer.

The horizontal area 630S of the second conductive layer may be disposed between the area 200a of the conductive structure 20 and the horizontal area 620S of the dielectric layer. The area 200a of the conductive structure 20 may be positioned in the first axis (X) direction from the horizontal area 630S of the second conductive layer.

The horizontal area 610S of the first conductive layer, the horizontal area 620S of the dielectric layer, the horizontal area 630S of the second conductive layer, and the area 200a of the conductive structure may be included in the horizontal area 10S of the base substrate 10.

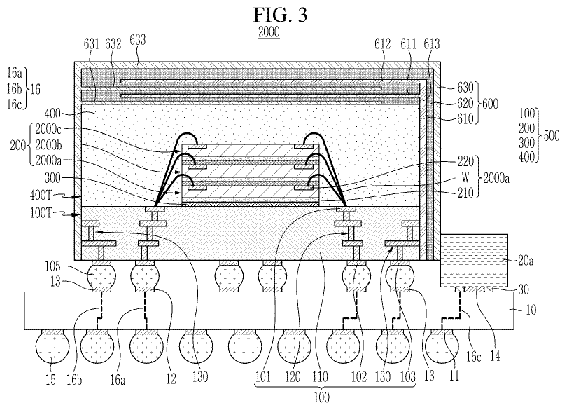

FIG. 3 is a cross-sectional view illustrating a semiconductor package according to an example embodiment.

Referring to FIG. 3, a semiconductor package 2000 may have features identical or similar to those described with reference to FIGS. 1 and 2 except that a semiconductor chip 200 which is disposed on a package substrate 100 is a chip in which a plurality of semiconductor chips 2000a, 2000b, and 2000c is sequentially stacked.

A package body 500 may include the package substrate 100, the semiconductor chip 200 in which the plurality of semiconductor chips 2000a, 2000b, and 2000c is sequentially stacked, an adhesive film 300, and a sealing layer 400. Each of the plurality of semiconductor chips 2000a, 2000b, and 2000c may include an adhesive film 210, wire W, and a conductive pad 220.

The plurality of semiconductor chips 2000a, 2000b, and 2000c may include memory chips or memory devices which store or output data on the basis of an address, a command, and data received from the package substrate 100. Each of the plurality of semiconductor chips 2000a, 2000b, and 2000c may include a logic circuit including a CPU, a GPU, an FPGA, an AP, a DSP, a cryptographic processor, a microprocessor, a micro controller, an analog-to-digital converter, or an ASIC, or a memory circuit including a volatile memory including a DRAM or an SRAM or a non-volatile memory including a PRAM, an MRAM, an RRAM, or a flash memory, and so on.

The semiconductor chip 2000a may be attached to the upper surface of the package substrate 100 using an adhesive film 210. The semiconductor chip 2000b may be attached to the upper surface of the semiconductor chip 2000a, using an adhesive film 210. The semiconductor chip 2000c may be attached to the upper surface of the semiconductor chip 2000b, using an adhesive film 210.

The semiconductor chip 2000a may be electrically connected to the package substrate 100 through conductive wire W connecting a conductive pad 220 and the upper pad 101 of the package substrate 100. The semiconductor chip 2000b may be electrically connected to the package substrate 100 through conductive wire W connecting a conductive pad 220 and the upper pad 101 of the package substrate 100. The semiconductor chip 2000c may be electrically connected to the package substrate 100 through conductive wire W connecting a conductive pad 220 and the upper pad 101 of the package substrate 100.

The package substrate 100 may transmit a data signal, received from the semiconductor chip 200 which is disposed thereon and in which the plurality of semiconductor chips 2000a, 2000b, and 2000c is sequentially stacked, to the outside. The package substrate may transmit a data signal and a power signal, received from the outside, to the semiconductor chip 200 in which the plurality of semiconductor chips 2000a, 2000b, and 2000c is sequentially stacked.

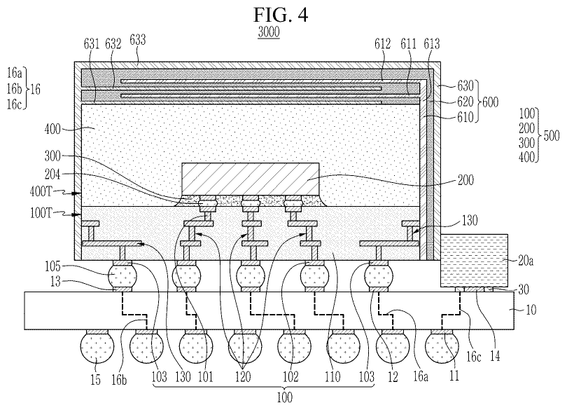

FIG. 4 is a cross-sectional view illustrating a semiconductor package according to an example embodiment.

Referring to FIG. 4, a semiconductor package 3000 may have features identical or similar to those described with reference to FIGS. 1 to 3 except that a semiconductor chip (reference symbol “200” in FIG. 1) which is disposed on a package substrate (reference symbol “100” in FIG. 1) is in the flip chip form. For example, the semiconductor chip 200 may be disposed on the package substrate 100, using an adhesive film 300.

The adhesive film 300 may surround bump structures 204 disposed between the package substrate 100 and the semiconductor chip 200 among a plurality of bump structures 204. The adhesive film 300 may be an underfill layer which fixes the semiconductor chip 200 on the package substrate 100. The underfill layer may contain an insulating material. The underfill layer may be formed using a copper finishing (CUF) process.

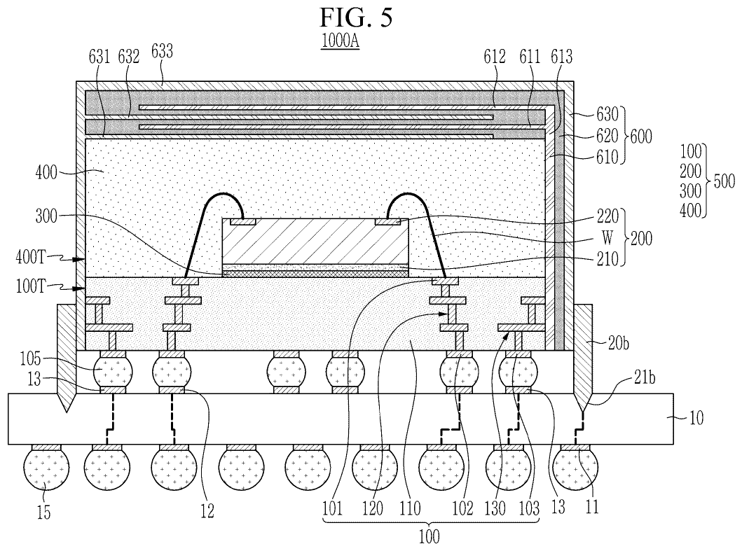

FIG. 5 is a cross-sectional view illustrating a semiconductor package according to an example embodiment of the present disclosure.

Referring to FIG. 5, a semiconductor package 1000A according to an example embodiment may have features identical or similar to those described with reference to FIGS. 1 to 3 except that a partial conductive structure 20b, which is a portion of a conductive structure (reference symbol “20a” in FIG. 1), which is disposed on a base substrate 10 and is in contact with the outer surface of a capacitor structure 600, is mounted in such a manner that it is inserted into a recessed portion of the base substrate 10.

The partial conductive structure 20b may be inserted into an insertion portion 21b which is disposed in the upper portion of the base substrate 10. The insertion portion may be in the form of a socket. The partial conductive structure 20b may be electrically connected to one or more connection wiring lines of a plurality of connection wiring lines of the base substrate 10.

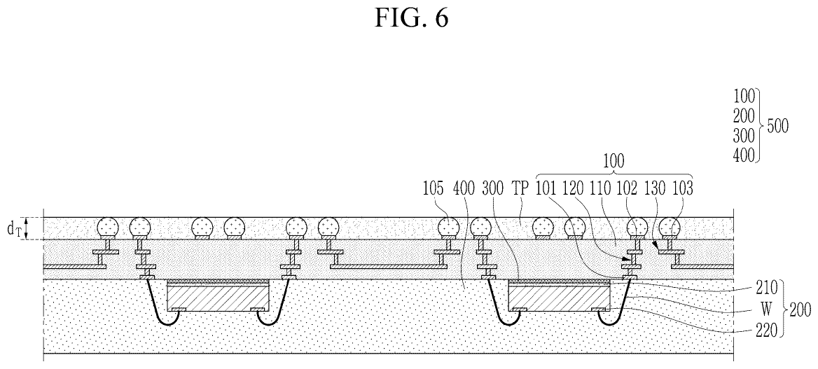

FIGS. 6 to 8 are cross-sectional views schematically illustrating a process of manufacturing a semiconductor package according to an example embodiment of the present disclosure.

Referring to FIG. 6, a ‘first package assembly’ may be provided in a face-up position. The first package assembly may include a package substrate 100 transversely extended. A plurality of semiconductor chips 200 which is attached to one surface of the package substrate 100 by an adhesive film 300 may be transversely arranged and disposed. A sealing layer 400 which surrounds the plurality of semiconductor chips 200 on one surface of the package substrate 100 may be disposed. On another surface of the package substrate 100, a plurality of bump structures 105 may be disposed.

Referring to FIG. 6, for a deposition process, a tape TP may be attached to surround the plurality of bump structures 105 connected to another surface of the package substrate 100. The tape TP may contain a UV-curable polymer. The tape TP may contain a polyester-acrylate-resin-based material, or an epoxy-acrylate-resin-based material. The tape TP may be formed to a desired (or alternatively, predetermined) thickness dT.

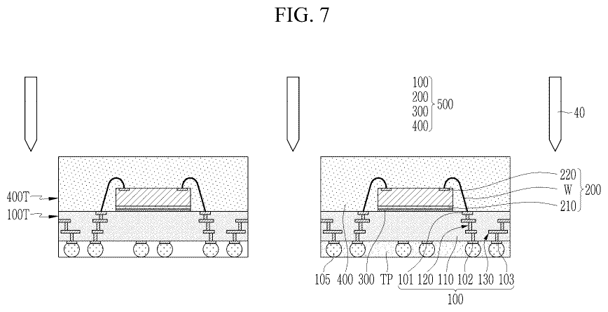

Referring to FIG. 7, the first package assembly may be cut with a cutter 40 by a sawing process. The cutter 40 may include a laser technology of a carbon dioxide laser, a fiber laser, an ultraviolet laser, etc. The package substrate 100 may be cut in a direction perpendicular to another surface of the package substrate 100. Through the sawing process, a plurality of package bodies 500 may be provided. A portion of the second wiring layer 130 of the package substrate 100 may be exposed from the side surface 100T of the package substrate 100.

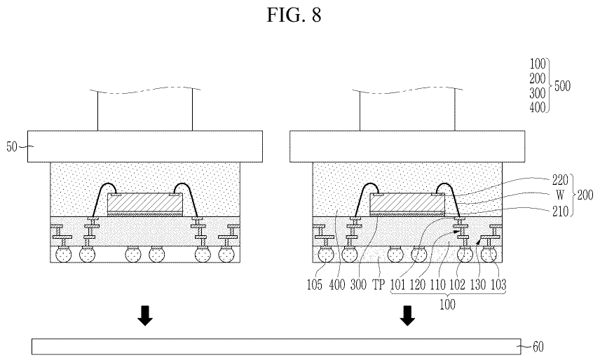

Referring to FIG. 8, the plurality of package bodies 500 may be picked up with a bonding head 50 by vacuum adsorption. The plurality of package bodies 500 may be disposed on a support substrate 60. The support substrate 60 may contain an insulating polymer material such as polyimide, and may be provided in the form of film.

In a process of depositing a plurality of conductive layers (reference symbols “610” and “630” in FIG. 1) for shielding on the side surfaces and upper surface of the package body 500, a process of depositing a dielectric layer (reference symbol “620” in FIG. 1) may be additionally performed. In the process of depositing the plurality of conductive layers 610 and 630 for shielding on the side surfaces and upper surface of the package body 500, an electrical connection relationship of some portions of the plurality of conductive layers 610 and 630 may be formed. In the process of depositing the plurality of conductive layers 610 and 630 for shielding on the side surfaces and upper surface of the package body 500, a semiconductor package (reference symbol “1000” in FIG. 1) using the dielectric layer 620 as a portion of a capacitor may be generated.

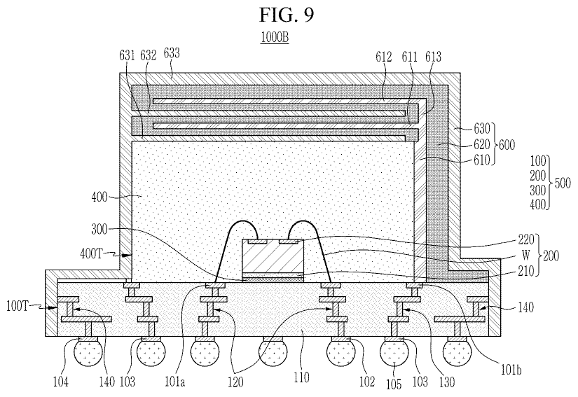

FIG. 9 is a cross-sectional view illustrating a semiconductor package according to an example embodiment of the present disclosure.

Referring to FIG. 9, in a semiconductor package 1000B, the horizontal area of a package substrate 100 may be larger than the horizontal area of a sealing layer 400. One surface and another surface of the package substrate 100 may be surrounded by a second conductive layer 630. The package substrate 100 may include a third wiring layer 140. Except for this, the semiconductor package 1000B may have features identical or similar to those of the semiconductor package 1000 of FIG. 1.

The package substrate 100 may include the first wiring layer 120, the second wiring layer 130, and the third wiring layer 140. The first wiring layer 120 may be connected to a first upper pad 101a connected to conductive wiring line W of the semiconductor chip 200. The second wiring layer 130 may be connected to a second upper pad 101b which is in contact with the first conductive layer 610. The second wiring layer 130 may be electrically connected to the first conductive layer 610. The third wiring layer 140 may be connected to the second conductive layer 630 on one surface and another surface of the package substrate 100. The second wiring layer 130 may be electrically connected to the second conductive layer 630. Each of the plurality of wiring layers 120, 130, and 140 may be electrically insulated.

The second wiring layer 130 may provide an electrical connection path to the first conductive layer 610. The first conductive layer 610 may receive the first voltage V1 through the second wiring layer 130. The third wiring layer 140 may provide an electrical connection path to the second conductive layer 630. The second conductive layer 630 may receive the second voltage V2 through the third wiring layer 140. The first voltage V1 applied to the first conductive layer 610 may be larger than the second voltage V2 applied to the second conductive layer 630. The first voltage V1 may be Vdd (e.g., a supply voltage), and the second voltage V2 may be Vss (e.g., a ground voltage).

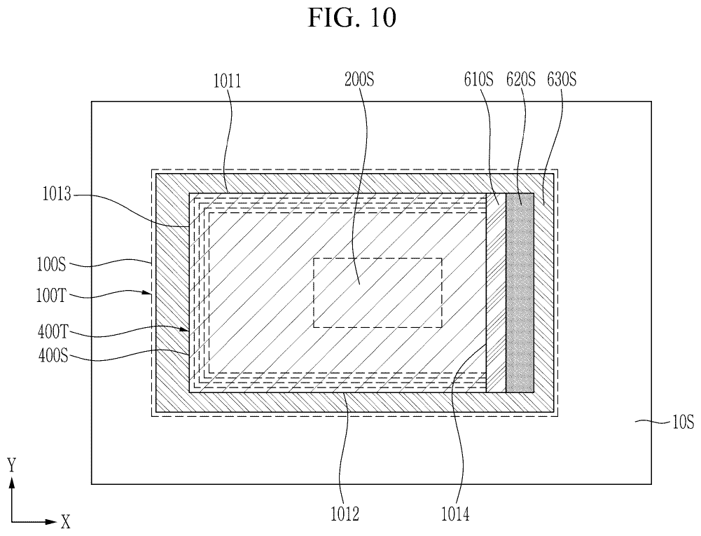

FIG. 10 is a top view of the semiconductor package of FIG. 9 as seen from above.

Referring to FIG. 10, the horizontal area 400S of the sealing layer 400 covering the semiconductor chip 200 may be smaller than the horizontal area 100S of the package substrate 100. The side surface 100T of the package substrate 100 may be positioned so as to protrude in the first axis (X) direction from the side surface 400T of the sealing layer 400. For example, the side surface 100T of the package substrate 100 may be positioned on the outer side from the side surface 400T of the sealing layer 400. The side surface 100T of the package substrate 100 may not be coplanar with the side surface 400T of the sealing layer 400 in the second axis (Y) direction.

The horizontal area 100S of the package substrate 100 may be included in the horizontal area 10S of the substrate (reference symbol “10” in FIG. 1). The horizontal area 100S of the package substrate 100 may be surrounded by the horizontal area 610S of the first conductive layer and the horizontal area 630S of the second conductive layer.

A first edge 1011 and a second edge 1012 in the horizontal area 100S of the package substrate 100 may be surrounded by the horizontal area 630S of the second conductive layer in the second axis (Y) direction. A third edge 1013 in the horizontal area 100S may be surrounded by the horizontal area 630S of the second conductive layer in the first axis (X) direction. A fourth edge 1014 in the horizontal area 100S may be surrounded by the horizontal area 610S of the first conductive layer in the first axis (X) direction.

The horizontal area 610S of the first conductive layer may be disposed between the horizontal area 620S of the dielectric layer and the horizontal area 400S of the sealing layer 400. The horizontal area 620S of the dielectric layer may be positioned in the first axis (X) direction from the horizontal area 610S of the first conductive layer.

The horizontal area 620S of the dielectric layer may be disposed between the horizontal area 630S of the second conductive layer and the horizontal area 610S of the first conductive layer. The horizontal area 630S of the second conductive layer may be positioned in the first axis (X) direction from the horizontal area 620S of the dielectric layer.

The horizontal area 630S of the second conductive layer may be positioned in the second axis (Y) direction of the horizontal area 610S of the first conductive layer and the horizontal area 620S of the dielectric layer. The horizontal area 610S of the first conductive layer and the horizontal area 620S of the dielectric layer may be surrounded by the horizontal area 630S of the second conductive layer and the horizontal area 100S of the package substrate 100.

The horizontal area 610S of the first conductive layer, the horizontal area 620S of the dielectric layer, and the horizontal area 630S of the second conductive layer may be included in the horizontal area 100S of the base substrate 10.

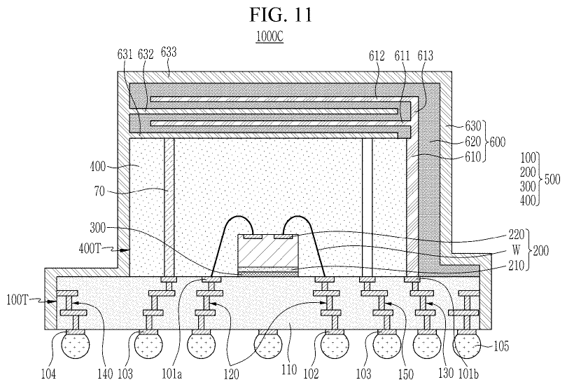

FIG. 11 is a cross-sectional view illustrating a semiconductor package according to an example embodiment of the present disclosure.

Referring to FIG. 11, a semiconductor package 1000C may include a connection structure 70 inside a sealing layer 400. The semiconductor package 1000C may include a fourth wiring layer 150. Except for the configuration of the connection structure 70 and the fourth wiring layer 150, the semiconductor package 1000C may have features identical or similar to those of the semiconductor package 1000B of FIG. 9.

Inside the sealing layer 400, a connection structure 70 which electrically connects the second conductive layer 630 and the second upper pad 101b may be disposed. The connection structure 70 may contain a conductive material. The connection structure 70 may include a metal material including tin (Sn), iron (Fe), nickel (Ni), or an alloy thereof. The connection structure 70 may have a pillar-like structure. The connection structure 70 may be in the form of wire. Below the connection structure 70, a wire ball may be formed. A wire body may be formed to extend from the wire ball. The wire ball connecting the wire body and the second upper pad 101b may be disposed. The connection structure 70 may be disposed to extend in a direction perpendicular to the upper surface of the package substrate 100 and to be inside the sealing layer 400.

The fourth wiring layer 150 may be connected to the second upper pad 101b exposed from the upper end of the package substrate 100. The fourth wiring layer 150 may be electrically connected to the connection structure 70 through the upper pad 101b.

The second conductive layer 630 may cover the upper surface of the sealing layer 400. The fourth wiring layer 150 may provide an electrical connection path to the second conductive layer 630 through the second upper pad 101b and the connection structure 70. The second conductive layer 630 may receive the second voltage V2 through the fourth wiring layer 150.

The second conductive layer 630 may extend along one side surface of the package substrate 100. The second conductive layer 630 may be connected to the third wiring layer 140 of the package substrate on one side surface of the package substrate. The third wiring layer 140 may provide an electrical connection path to the second conductive layer 630. The second conductive layer 630 may receive the second voltage V2 through the third wiring layer 140.

The first conductive layer 610 may extend along another surface of the package substrate 100. The first conductive layer 610 may be connected to the second wiring layer 130 of the package substrate on another side surface of the package substrate. The second wiring layer 130 may provide an electrical connection path to the first conductive layer 610. The first conductive layer 610 may receive a first voltage V1 through the second wiring layer 130.

The first voltage V1 which is applied to the first conductive layer 610 may be larger than the second voltage V2 which is applied to the second conductive layer 630. The first voltage V1 may be Vdd (e.g., a supply voltage), and the second voltage V2 may be Vss (e.g., a ground voltage).

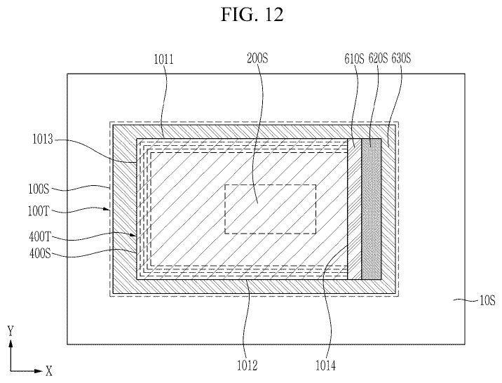

FIG. 12 is a top view of the semiconductor package of FIG. 11 as seen from above.

Referring to FIG. 12, the horizontal area 400S of the sealing layer 400 covering the semiconductor chip 200 may be smaller than the horizontal area 100S of the package substrate 100. The side surface 100T of the package substrate 100 may be positioned so as to protrude in the first axis (X) direction from the side surface 400T of the sealing layer 400. For example, the side surface 100T of the package substrate 100 may be positioned on the outer side from the side surface 400T of the sealing layer 400. The side surface 100T of the package substrate 100 may not be coplanar with the side surface 400T of the sealing layer 400 in the second axis (Y) direction.

The horizontal area 100S of the package substrate 100 may be included in the horizontal area 10S of the substrate 10 (reference symbol “10” in FIG. 1). The horizontal area 100S of the package substrate 100 may be surrounded by the horizontal area 610S of the first conductive layer and the horizontal area 630S of the second conductive layer.

A first edge 1011 and a second edge 1012 in the horizontal area 100S of the package substrate 100 may be surrounded by portions of the horizontal area 630S of the second conductive layer in the second axis (Y) direction, respectively. A third edge 1013 in the horizontal area 100S may be surrounded by a portion of the horizontal area 630S of the second conductive layer in the first axis (X) direction. A fourth edge 1014 in the horizontal area 100S may be surrounded by the horizontal area 610S of the first conductive layer in the first axis (X) direction.

The horizontal area 610S of the first conductive layer may be disposed between the horizontal area 630S of the second conductive layer and the horizontal area 400S of the sealing layer 400. The horizontal area 630S of the second conductive layer may be positioned in the first axis (X) direction from the horizontal area 610S of the first conductive layer.

The horizontal area 630S of the second conductive layer may be positioned in the second axis (Y) direction of the horizontal area 610S of the first conductive layer. The horizontal area 610S of the first conductive layer may be surrounded by the horizontal area 630S of the second conductive layer and the horizontal area 100S of the package substrate 100.

The horizontal area 610S of the first conductive layer and the horizontal area 630S of the second conductive layer may be included in the horizontal area 100S of the substrate 10.

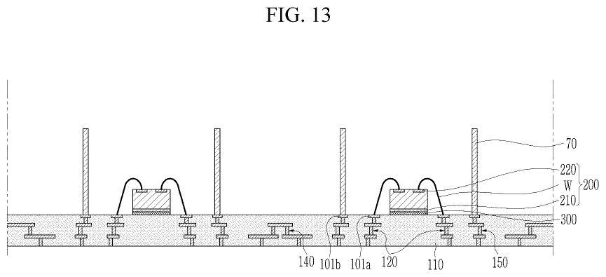

FIGS. 13 to 15 are cross-sectional views schematically illustrating a process of manufacturing the semiconductor package 1000C according to the example embodiment of the present disclosure.

Referring to FIG. 13, a plurality of semiconductor chips 200 attached to at least a portion of the upper surface of the insulating layer 110, transversely extended, by the adhesive film 300 may be provided. The connection structure 70 may be formed so as to be connected to some of the upper pads 101a and 101b exposed from the upper surface of the package substrate 100. The connection structure 70 may be a pillar-like structure. The connection structure 70 may be formed to extend in a direction perpendicular to the upper surface of the package substrate 100. The connection structure 70 may also be formed in the form of wire. Below the connection structure 70 and on the second upper pad 101b, wire balls (not shown) may be formed. A wire body (not shown) may be formed to extend from the wire balls. In this case, the wire body may be formed to form an arbitrary angle (larger than 0° and smaller than 90°) with the upper surface of the package substrate 100.

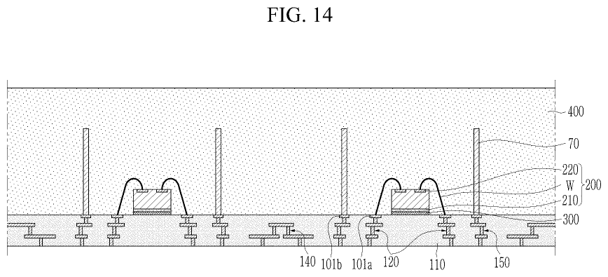

Referring to FIG. 14, the sealing layer 400 may encapsulate the semiconductor chip 200 and the connection structure 70 on the package substrate 100 so as to surround them.

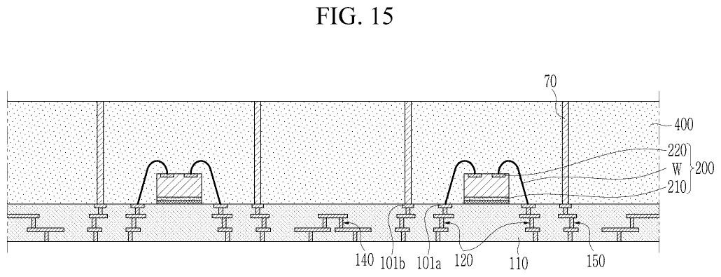

Referring to FIG. 15, the upper surface of the sealing layer 400 may be planarized to be coplanar with the upper surface of the connection structure 70. As the planarizing process, for example, a chemical mechanical polishing (CMP) process may be performed.

In a process of depositing a plurality of conductive layers (reference symbols “610” and “630” in FIG. 1) for shielding on the side surfaces and upper surface of the package body 500, a process of depositing a dielectric layer (reference symbol “620” in FIG. 1) may be additionally performed. In the process of depositing the plurality of conductive layers 610 and 630 for shielding on the side surfaces and upper surface of the package body 500, an electrical connection relationship of some portions of the plurality of conductive layers 610 and 630 may be formed. In the process of depositing the plurality of conductive layers 610 and 630 for shielding on the side surfaces and upper surface of the package body 500, a semiconductor package (reference symbol “1000” in FIG. 1) using the dielectric layer 620 as a portion of a capacitor may be generated.

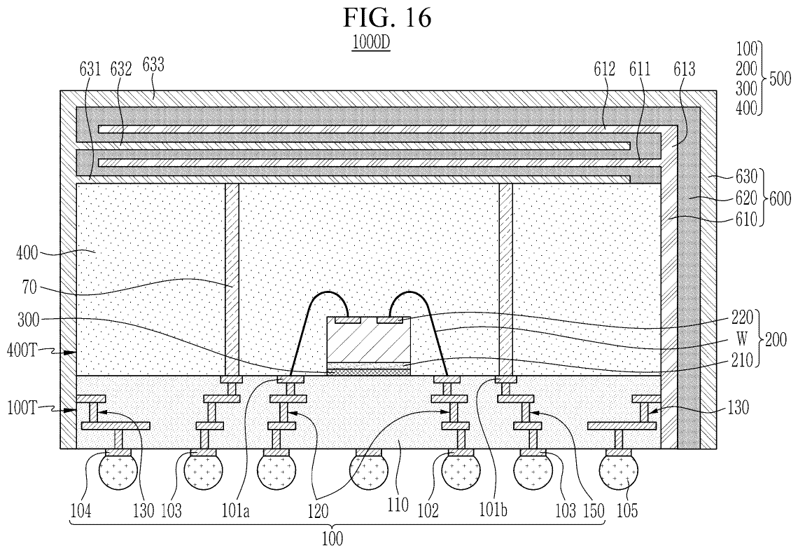

FIG. 16 is a cross-sectional view illustrating a semiconductor package according to an example embodiment of the present disclosure.

Referring to FIG. 16, in a semiconductor package 1000D, the horizontal area of a package substrate 100 may be equal to the horizontal area of a sealing layer 400. One surface and another surface of the package substrate 100 may be surrounded by the first conductive layer 610 and the second conductive layer 630, respectively. Except for this, the semiconductor package 1000D may have features identical or similar to those of the semiconductor package 1000C of FIG. 11.

The second conductive layer 630 may be disposed to cover the upper surface of the sealing layer 400. The fourth wiring layer 150 may provide an electrical connection path to the second conductive layer 630 through the second upper pad 101b and the connection structure 70. The second conductive layer 630 may receive the second voltage V2 through the fourth wiring layer 150.

The second conductive layer 630 may extend along one side surface of the package substrate 100. The second conductive layer 630 may be connected to the second wiring layer 130 of the package substrate 100. The second wiring layer 130 may provide an electrical connection path to the second conductive layer 630. The second conductive layer 630 may receive the second voltage V2 through the second wiring layer 130.

The first conductive layer 610 may extend along another surface of the package substrate 100. The first conductive layer 610 may be connected to the second wiring layer 130 of the package substrate 100. The second wiring layer 130 may provide an electrical connection path to the first conductive layer 610. The first conductive layer 610 may receive a first voltage V1 through the second wiring layer 130.

The first voltage V1 which is applied to the first conductive layer 610 may be larger than the second voltage V2 which is applied to the second conductive layer 630. The first voltage V1 may be Vdd (e.g., a supply voltage), and the second voltage V2 may be Vss (e.g., a ground voltage).

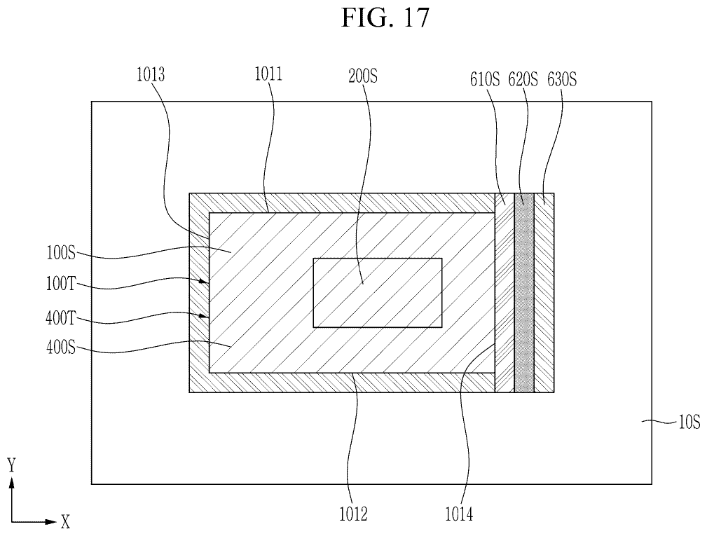

FIG. 17 is a top view illustrating of the semiconductor package of FIG. 16 as seen from above.

Referring to FIG. 17, the horizontal area 100S of the package substrate (reference symbol “100” in FIG. 1) in the first axis (X) direction and the second axis (Y) direction may be equal to the horizontal area 400S of the sealing layer (reference symbol “400” in FIG. 1) in the first axis (X) direction and the second axis (Y) direction. The side surface 100T of the package substrate 100 may be coplanar with the side surface 400T of the sealing layer 400 in the second axis (Y) direction.

The horizontal area 100S of the package substrate 100 may be included in the horizontal area 10S of the substrate (reference symbol “10” in FIG. 1). The horizontal area 100S of the package substrate 100 may be surrounded by the horizontal area 610S of the first conductive layer and the horizontal area 630S of the second conductive layer. A first edge 1011 and a second edge 1012 in the horizontal area 100S of the package substrate 100 may be surrounded by portions of the horizontal area 630S of the second conductive layer in the second axis (Y) direction, respectively. A third edge 1013 in the horizontal area 100S may be surrounded by the horizontal area 630S of the second conductive layer in the first axis (X) direction. A fourth edge 1014 in the horizontal area 100S may be surrounded by the horizontal area 610S of the first conductive layer in the first axis (X) direction.

The horizontal area 610S of the first conductive layer may be disposed between the horizontal area 620S of the dielectric layer and the horizontal area 100S of the package substrate 100. The horizontal area 620S of the dielectric layer may be positioned in the first axis (X) direction from the horizontal area 610S of the first conductive layer.

The horizontal area 620S of the dielectric layer may be disposed between the horizontal area 630S of the second conductive layer and the horizontal area 610S of the first conductive layer. The horizontal area 630S of the second conductive layer may be positioned in the first axis (X) direction from the horizontal area 620S of the dielectric layer.

The horizontal area 610S of the first conductive layer, the horizontal area 620S of the dielectric layer, and the horizontal area 630S of the second conductive layer may be included in the horizontal area 100S of the substrate 10.

While the inventive concepts have been described in connection with what is presently considered to be practical example embodiments, it is to be understood that the inventive concepts are not limited to the disclosed example embodiments. On the contrary, it is intended to cover various modifications and equivalent arrangements included within the spirit and scope of the appended claims.

What is claimed is:

1. A semiconductor package comprising:
a package substrate including a plurality of upper pads;
a semiconductor chip on the package substrate and electrically connected to at least one of the plurality of upper pads;
a sealing layer configured to cover at least a portion of the semiconductor chip and the package substrate; and
a capacitor structure including a first conductive layer configured to cover one side surface of the package substrate and a portion of the sealing layer, a second conductive layer configured to cover another side surface of the package substrate and another portion of the sealing layer, and a dielectric layer being between the first conductive layer and the second conductive layer.

2. The semiconductor package of claim 1, further comprising:
a conductive structure in contact with an outer surface of the second conductive layer;
a base substrate below the package substrate and the conductive structure;
a plurality of connection bumps below the base substrate; and
a connection wiring line connecting one of the plurality of connection bumps to the conductive structure.

3. The semiconductor package of claim 2, wherein:
the first conductive layer includes
a first cover region in contact with one side surface of the sealing layer and one side surface of the package substrate,
a first branch region branching from the first cover region and is positioned in an upper portion of the sealing layer, and
a second branch region branching from the first cover region, the second branch region being spaced apart from the first branch region and being on the first branch region.

4. The semiconductor package of claim 3, wherein:
the second conductive layer includes
a second cover region in contact with another side surface of the sealing layer and another surface of the package substrate, the second cover region defining an upper end of the capacitor structure,
a third branch region branching from the second cover region and being in contact with an upper end of the sealing layer, and
a fourth branch region branching from the second cover region, the fourth branch region being spaced apart from the third branch region and being on the third branch region.

5. The semiconductor package of claim 4, wherein:
the dielectric layer includes
a first region between the third branch region and the first branch region,
a second region between the first branch region and the fourth branch region,
a third region between the fourth branch region and the second branch region, and
a fourth region between the second branch region and the second cover region.

6. The semiconductor package of claim 2, wherein:
the package substrate further includes
a plurality of first wiring layers connected to the plurality of upper pads; and
a second wiring layer connected to the first conductive layer.

7. The semiconductor package of claim 6, wherein:
the first conductive layer is further configured to receive a first voltage through the second wiring layer, and
the second conductive layer is further configured to receive a second voltage lower than the first voltage through the conductive structure.

8. The semiconductor package of claim 6, wherein:
a horizontal area of the package substrate is larger than a horizontal area of the sealing layer, and
the package substrate further includes a third wiring layer connected to each of one side surface and another side surface of the package substrate.

9. The semiconductor package of claim 8, wherein:
the first conductive layer is further configured to receive a first voltage through the second wiring layer, and
the second conductive layer is further configured to receive a second voltage lower than the first voltage through the third wiring layer.

10. The semiconductor package of claim 6, wherein:
the package substrate includes a third wiring layer connected to at least one of the plurality of upper pads,
the sealing layer includes at least one connection structure electrically connected to the third wiring layer, and
the second conductive layer is electrically connected to the at least one connection structure.

11. The semiconductor package of claim 10, wherein:
the first conductive layer is further configured to receive a first voltage through the second wiring layer, and
the second conductive layer is further configured to receive a second voltage lower than the first voltage through the third wiring layer and the connection structure.

12. The semiconductor package of claim 11, wherein:
a horizontal area of the package substrate is larger than a horizontal area of the sealing layer, and
the package substrate further includes a fourth wiring layer connected to each of one side surface and another side surface of the package substrate.

13. The semiconductor package of claim 12, wherein:
the first conductive layer is further configured to receive a first voltage through the second wiring layer, and
the second conductive layer is further configured to receive a second voltage lower than the first voltage through the fourth wiring layer.

14. The semiconductor package of claim 6, wherein:
the semiconductor chip includes an adhesive film bonding the semiconductor chip to an upper surface of the package substrate.

15. The semiconductor package of claim 14, wherein:
the semiconductor package includes a plurality of bump structures between the package substrate and the semiconductor chip,
the plurality of bump structures are electrically connected to corresponding ones of the first wiring layer, respectively, and
the adhesive film is configured to surround the plurality of bump structures and fix the semiconductor chip on the package substrate.

16. The semiconductor package of claim 6, wherein:
a portion of the conductive structure is inserted into a recessed portion of the base substrate.

17. A semiconductor package comprising:
a package substrate including a plurality of upper pads;
a semiconductor chip on the package substrate and electrically connected to at least one of the plurality of upper pads;
a sealing layer configured to cover at least a portion of the semiconductor chip and the package substrate, the sealing layer including a connection structure electrically connected to a second conductive layer; and
a capacitor structure including a first conductive layer configured to cover one side surface of the package substrate and a portion of the sealing layer, the second conductive layer configured to cover another side surface of the package substrate and another portion of the sealing layer, and a dielectric layer being between the first conductive layer and the second conductive layer.

18. The semiconductor package of claim 17, wherein:
the package substrate includes
a plurality of first wiring layers connected to the plurality of upper pads,
a second wiring layer connected to the first conductive layer, and
a third wiring layer connected to the connection structure.

19. The semiconductor package of claim 18, wherein:
the first conductive layer is further configured to receive a first voltage through the second wiring layer, and
the second conductive layer is further configured to receive a second voltage lower than the first voltage through the connection structure and the third wiring layer.

20. A semiconductor package comprising:
a package body including
a package substrate including a first wiring layer and a second wiring layer,
a semiconductor chip on the package substrate and electrically connected to the first wiring layer, and
a sealing layer configured to cover at least a portion of the semiconductor chip and the package substrate;
a capacitor structure including
a first conductive layer in contact with one side surface of the package body,
a second conductive layer in contact with another side surface and an upper surface of the package body, and
a dielectric layer being between the first conductive layer and the second conductive layer;
a conductive structure in contact with the second conductive layer of the capacitor structure;
a base substrate including
a first connection wiring line below the package body and the conductive structure and electrically connected to the first wiring layer,
a second connection wiring line electrically connected to the second wiring layer, and
a third connection wiring line electrically connected to the conductive structure; and
a first connection bump, a second connection bump, and a third connection bump being below the base substrate and electrically connected to the first connection wiring line, the second connection wiring line, and the third connection wiring line, respectively.
